(19) United States
(12) Patent Application Publication
(10) Pub. No.: US 2007/0290248 A1
(43) Pub. Date: Dec. 20, 2007

(54) Manufacturing method for an integrated semiconductor structure and corresponding semiconductor structure

(76) Inventor: Rolf Weis, Dresden (DE)

Correspondence Address: ESCHWEILER & ASSOCIATES LLC, NATIONAL CITY BANK BUILDING, CLEVELAND, OH, 44114, US

(21) Appl. No.: 11/452,745

(22) Filed: Jun. 14, 2006

(51) Int. Cl. H01L 29/94; H01L 27/108; H01L 29/76; H01L 31/119

(52) U.S. Cl. 257/301

(57) ABSTRACT

The present invention provides a manufacturing method for an integrated semiconductor structure and a corresponding semiconductor structure. The method comprises the steps of: providing a semiconductor substrate having a plurality of trench capacitors which are arranged in rows and columns in a checkerboard layout; forming connection straps for electrically connecting said trench capacitors such that the connection straps of pairs of adjacent columns are facing each other, forming insulation trenches between said rows for defining active areas, each of which active areas is electrically connected to a connection strap of an associated trench capacitor on a first side and each of which is electrically insulated from a neighboring trench capacitor of said associated trench capacitor on a second side; forming electrically conducting landing pads between adjacent active areas for connecting pairs of said active areas, said landing pads being arranged in first lines in parallel to said columns; forming an insulation layer on said first insulating layer covering said landing pads; and forming a cell transistor for each trench capacitor which divides the active area of the associated trench capacitor in a first and second section, said cell transistors being arranged in second lines in parallel to said columns.

### BACKGROUND OF THE INVENTION

1. Field of the Invention

The present invention relates to a manufacturing method for an integrated semiconductor structure and to a corresponding semiconductor structure.

2. Description of the Related Art

Although in principle applicable to arbitrary integrated semiconductor structures, the following invention and the underlying problems will be explained with respect to integrated DRAM memory circuits in silicon technology.

DRAM technology which is scaled down to below 100 nm generation provides big challenges. One important issue is to keep the cell capacitance small to meet the retention requirements. In modern technology, a checkerboard deep trench pattern design is for the purpose of enlarging the deep trench dry etch process window for deeper trench depths and avoiding neighboring deep trench shorts. Checkerboard deep trench pattern also provide the necessary space for a wet bottle process to enhance the surface area of the bottom part of the trenches.

A shared bitline contact is known from the MINT layout where one bitline contact is shared within two adjacent cells on one active area line. Introducing the wet bottle process into the deep trench process, the deep trench pattern has to be changed to a checkerboard pattern. Due to this change the transition of one bitline contact per cell was necessary, too.

One bitline contact per cell, however, increases the bitline capacitance compared to shared bitline contact, as the major contribution is coupling over the gate contact spacer between the wordline and the bitline contact.

### BRIEF SUMMARY OF THE INVENTION

According to a first aspect of the invention as claimed in claim 1, a manufacturing method for an integrated semiconductor structure comprises the steps of: providing a semiconductor substrate having a plurality of trench capacitors which are arranged in rows and columns in a checkerboard layout; forming connection straps for electrically connecting said trench capacitors such that the connection straps of pairs of adjacent columns are facing each other, forming insulation trenches between said rows for defining active areas, each of which active areas is electrically connected to a connection strap of an associated trench capacitor on a first side and each of which is electrically insulated from a neighboring trench capacitor of said associated trench capacitor on a second side; forming electrically conducting landing pads between adjacent active areas for connecting pairs of said active areas, said landing pads being arranged in first lines in parallel to said columns; forming an insulation layer on said first insulating layer covering said landing pads; and forming a cell transistor for each trench capacitor which divides the active area of the associated trench capacitor in a first and second section, said cell transistors being arranged in second lines in parallel to said columns.

According to a second aspect of the invention as claimed in claim 14, a manufacturing method for an integrated semiconductor structure comprises the steps of: providing a semiconductor substrate having a plurality of trench capacitors which are arranged in rows and columns in a checkerboard layout; forming connection straps for electrically connecting said trench capacitors such that the connection straps of pairs of adjacent columns are facing each other; forming insulation trenches between said rows for defining active areas; forming connection lines on said active areas between said trench capacitors each of which is electrically connected to a connection strap of an associated trench capacitor on a first side and each of which is electrically insulated from a neighboring trench capacitor of said associated trench capacitor on a second side; forming electrically conducting landing pads between adjacent connection lines for connecting pairs of said connection lines, said landing pads being arranged in first lines in parallel to said columns; and forming a cell transistor for each trench capacitor which divides the connection line of the associated trench capacitor in first and second section, said cell transistors being arranged in second lines in parallel to said columns.

According to a third aspect of the invention as claimed in claim 17, an integrated semiconductor structure comprises: a semiconductor substrate having a plurality of trench capacitors which are arranged in rows and columns in a checkerboard layout; connection straps for electrically connecting said trench capacitors such that the connection straps of pairs of adjacent columns are facing each other; insulation trenches between said rows for defining active areas; connection lines on said active areas between said trench capacitors each of which is electrically connected to a connection strap of an associated trench capacitor on a first side and each of which is electrically insulated from a neighboring trench capacitor of said associated trench capacitor on a second side; electrically conducting landing pads between adjacent connection lines for connecting pairs of said connection lines, said landing pads being arranged in first lines in parallel to said columns; and a cell transistor for each trench capacitor which divides the connection line of the associated trench capacitor in first and second section, said cell transistors being arranged in second lines in parallel to said columns.

According to a fourth aspect of the invention as claimed in claim 20, an integrated semiconductor structure comprises: a semiconductor substrate having a plurality of trench capacitors which are arranged in rows and columns in a checkerboard layout; connection straps for electrically connecting said trench capacitors such that the connection straps of pairs of adjacent columns are facing each other; insulation trenches between said rows for defining active areas; connection lines on said active areas between said trench capacitors each of which is electrically connected to a connection strap of an associated trench capacitor on a first side and each of which is electrically insulated from a neighboring trench capacitor of said associated trench capacitor on a second side; a first insulation layer on said connection lines and on said insulation trenches; electrically conducting landing pads between adjacent connection lines for connecting pairs of said connection lines, said landing pads being arranged in first lines in parallel to said columns; a second insulation layer on said first insulating layer covering said landing pads; and forming a cell transistor for each trench capacitor which divides the connection line of the associated trench capacitor in first and second section, said cell transistors being arranged in second lines in parallel to said columns.

According to the present invention, a shared bit line contact can be used for a checkerboard deep trench pattern with introduction of vertical cell transistors fabricated with an own hole mask. Thus, there is a reduction of bit line capacitance compared to the known layout with one bit line contact per cell. Using single sided strap formation with a 2 F/2 F mask allows to form straps facing each other.

Preferred embodiments are listed in the respective dependent claims.

According to an embodiment, connection lines are formed on said active areas between said trench capacitors, each of which is electrically connected to a connection strap of an associated trench capacitor on a first side and each of which is electrically insulated from a neighboring trench capacitor of said associated trench capacitor on a second side, said electrically conducting landing pads being formed between said connection lines, said cell transistor dividing the connection lines of the associated trench capacitor in a corresponding first and second section.

According to another embodiment, a step of forming another insulation layer on said connection lines and on said insulation trenches is performed.

According to another embodiment, there is a step of forming wordlines on said second insulating layer which are electrically connected to respective groups of cell transistors arranged along said second lines.

According to another embodiment, there is a step of forming a third insulating layer on said second insulating layer covering said wordlines; forming bitline contacts for connecting said landing pads which extend through said first, second and third insulating layer; and forming bitlines on said third insulating layer which are electrically connected to respective groups of bitline contacts arranged in parallel to said rows.

According to another embodiment, said step of forming connection straps comprises forming mask stripes between said columns which partly mask a conductive infill of the trench capacitors of pairs of adjacent columns; performing an ion implantation into the not masked parts of said conductive infill of said trench capacitors for reoxidate the not masked parts of said conductive infill; removing said mask stripes; etching back a part of said conductive infill and a surrounding insulating collar; refilling said trench capacitors with another conductive infill; and etching back said another conductive infill such that connection straps are formed.

According to another embodiment, said step of forming said landing pads comprises: forming vias which extend through said first insulating layer and which partly expose upper portions of said connection lines; and filling said vias with a electrically conductive material which electrically contacts said exposed upper portions.

According to another embodiment, said step of forming said landing pads comprises: forming vias which extend through said first insulating layer and which partly extend through said connection lines and said insulation trenches and which partly expose sidewall portions of said connection lines; and filling said vias with a electrically conductive material which electrically contacts said sidewall portions.

According to another embodiment, said connection lines are made of polysilicon.

According to another embodiment, said cell transistor are EUD transistors or FINFET-like transistors.

According to another embodiment, said insulating layers are silicon oxide or nitride layers.

According to another embodiment, said step of forming a cell transistor comprises: forming a hole which extends through said first and second insulating layer and into said substrate such that it divides the connection line of the associated trench capacitor in said first and second section; and forming a gate in said hole which is electrically insulated by a sidewall spacer in the upper portion of said hole.

### DESCRIPTION OF THE DRAWINGS

In the Figures:

FIG. 1A-F show schematic layouts of a manufacturing method for an integrated semiconductor structure according to a first embodiment of the present invention;

FIG. 2A-D show schematic cross-sections of a strap forming sequence in the manufacturing method for an integrated semiconductor structure according to said first embodiment of the present invention;

FIG. 3A-G show schematic perspective views of the manufacturing method for an integrated semiconductor structure according to said first embodiment of the present invention;

FIG. 4A-C show schematic perspective views of the manufacturing method for an integrated semiconductor structure according to a second embodiment of the present invention; and

FIG. 5A-C show schematic perspective views of the manufacturing method for an integrated semiconductor structure according to a third embodiment of the present invention.

In the Figures, identical reference signs denote equivalent or functionally equivalent components.

### DESCRIPTION OF THE PREFERRED EMBODIMENTS

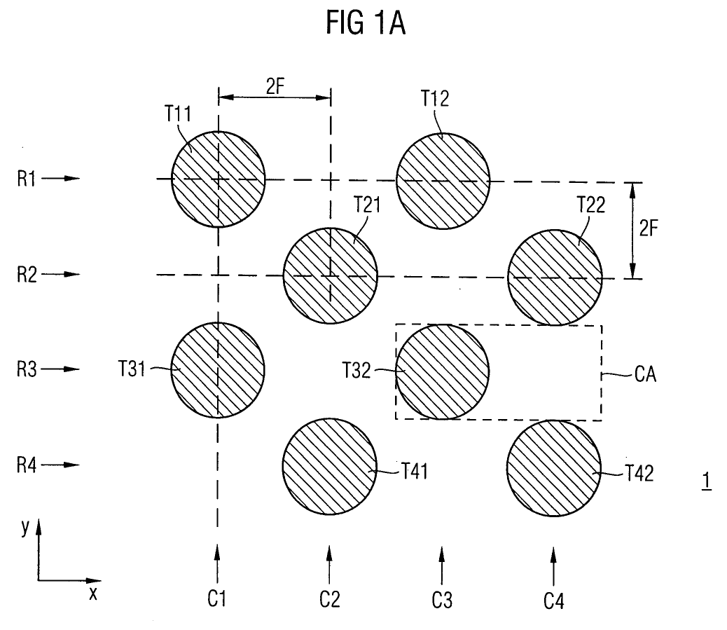

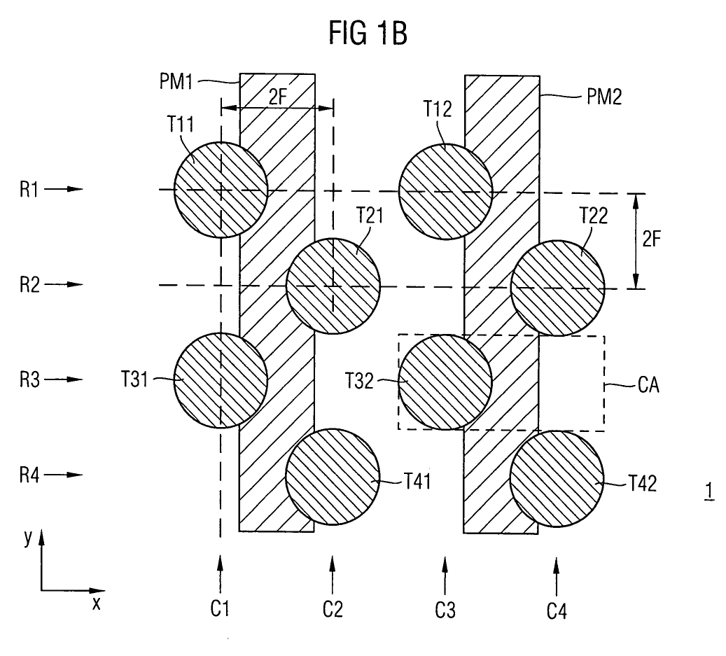

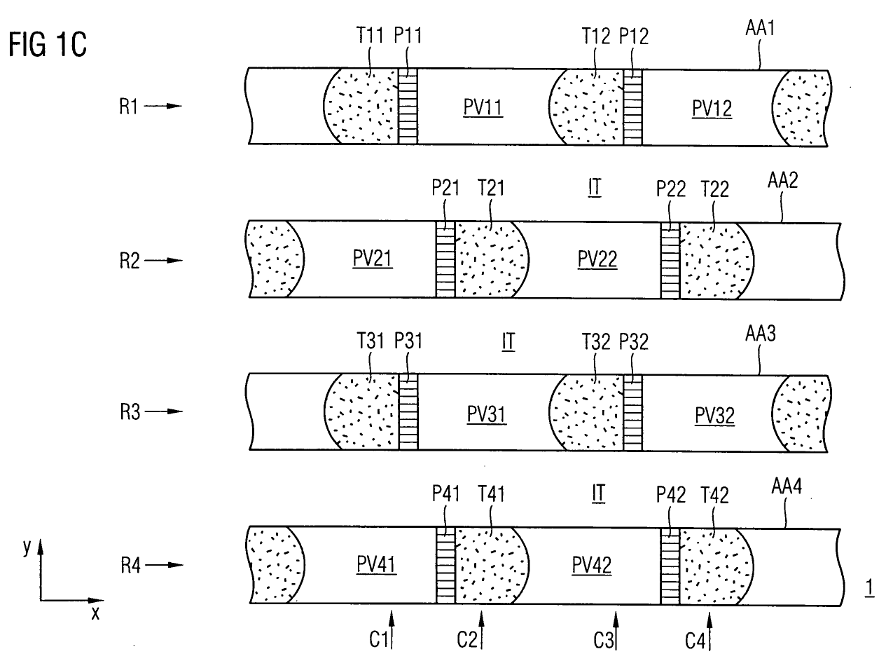

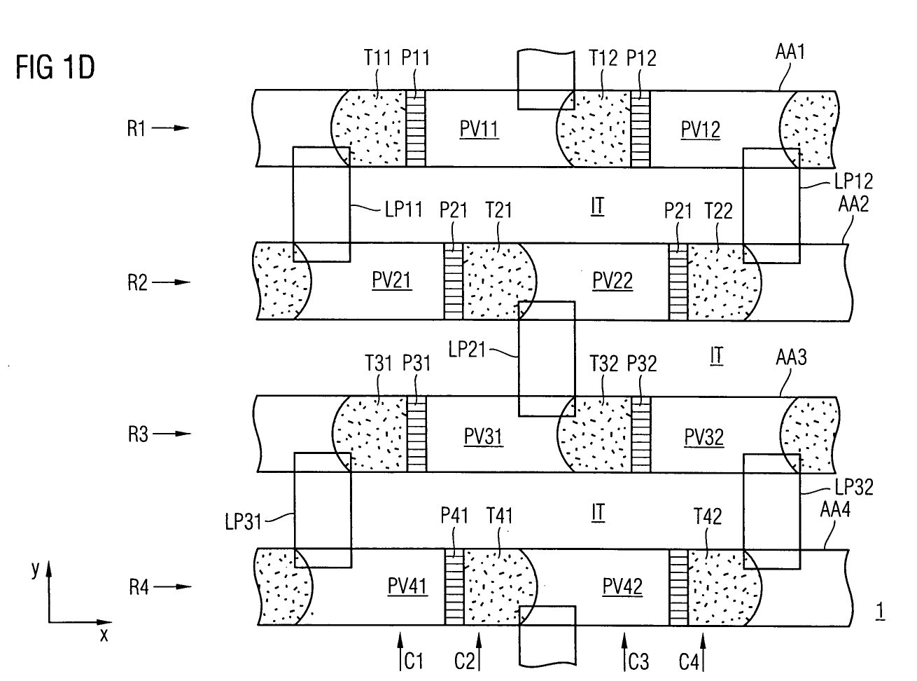

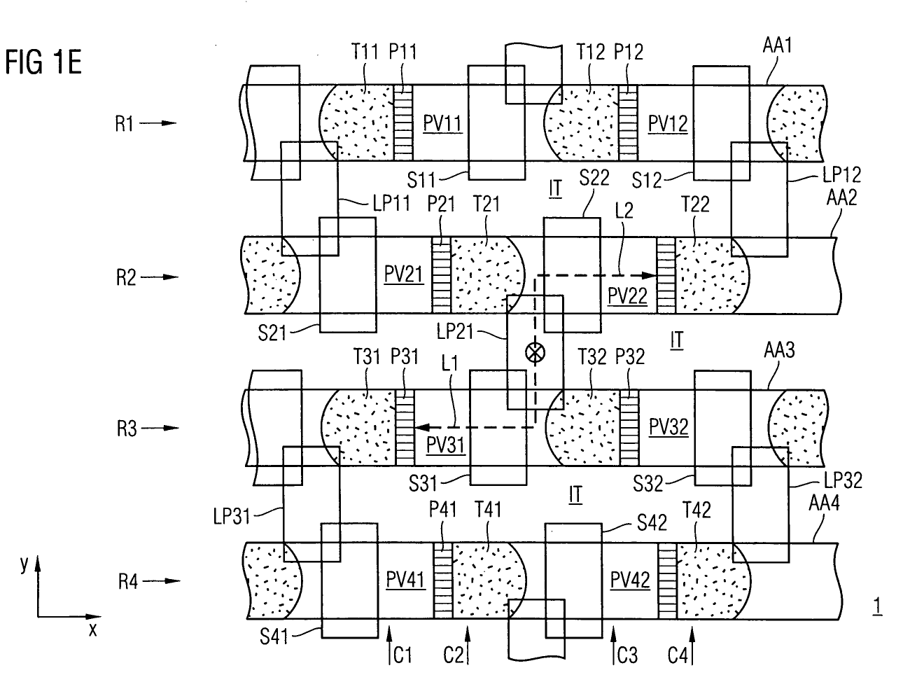

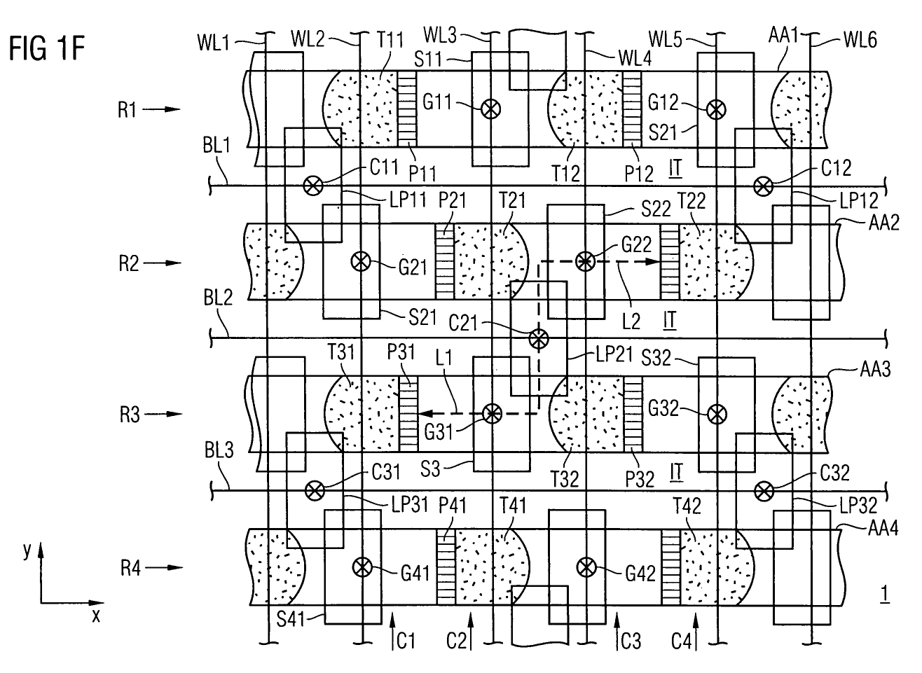

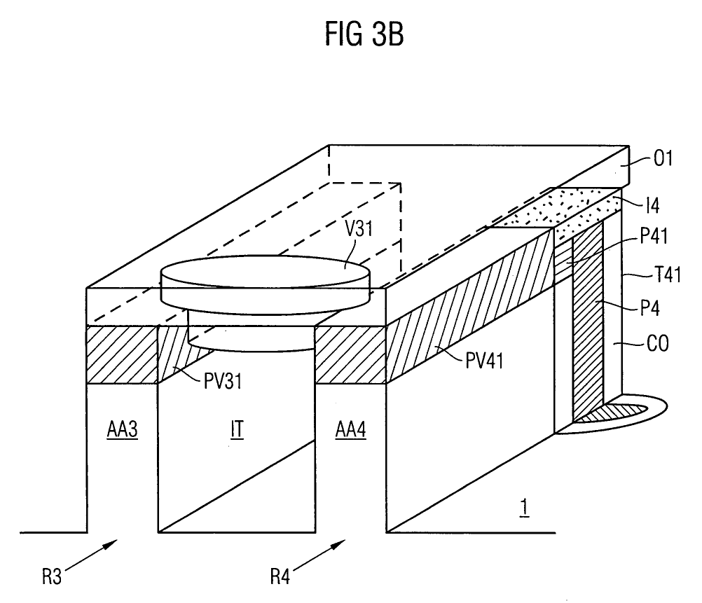

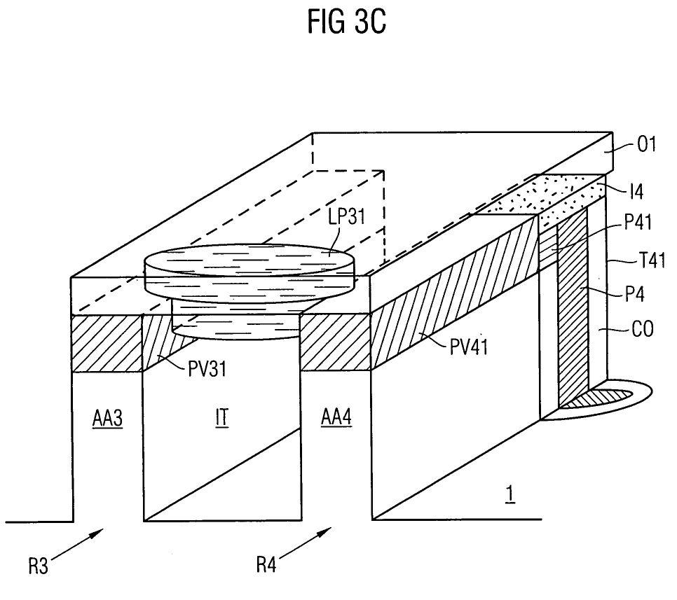

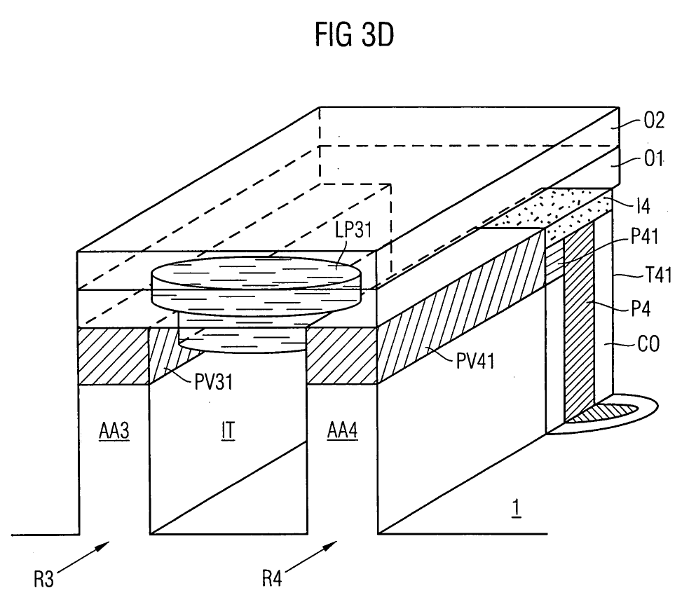

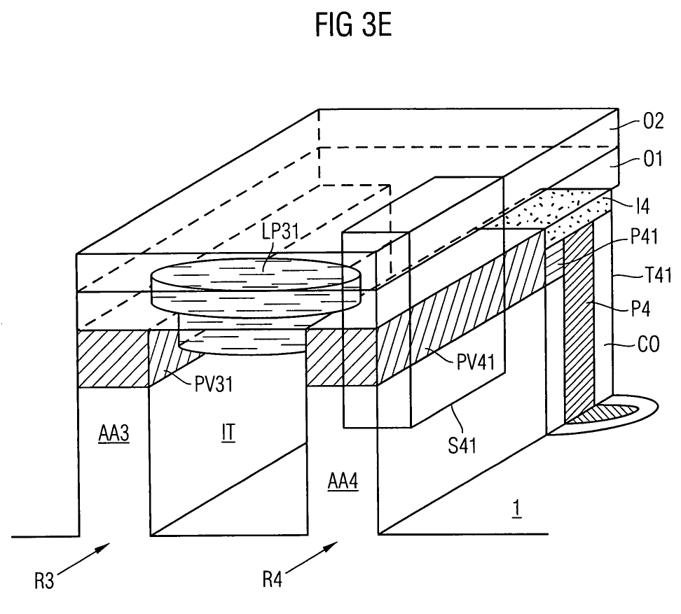

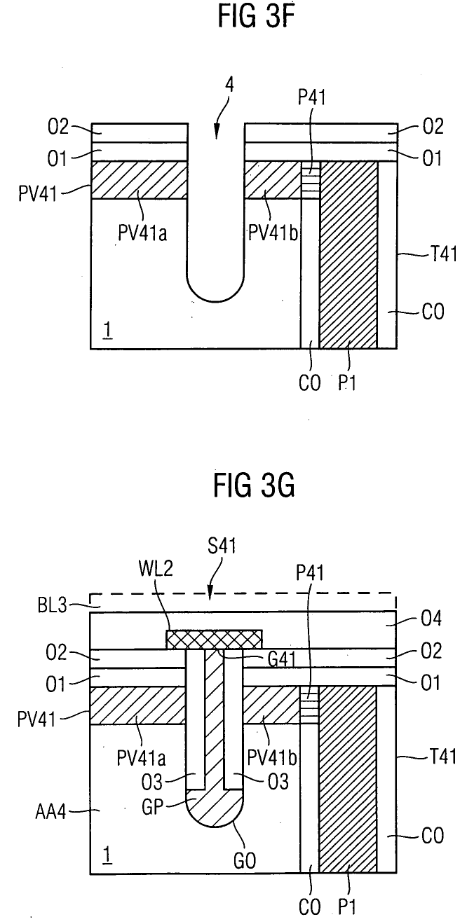

FIG. 1A-F show schematic layouts of a manufacturing method for an integrated semiconductor structure according to a first embodiment of the present invention, and FIG. 3A-G show schematic perspective views of the manufacturing method for an integrated semiconductor structure according to said first embodiment of the present invention.

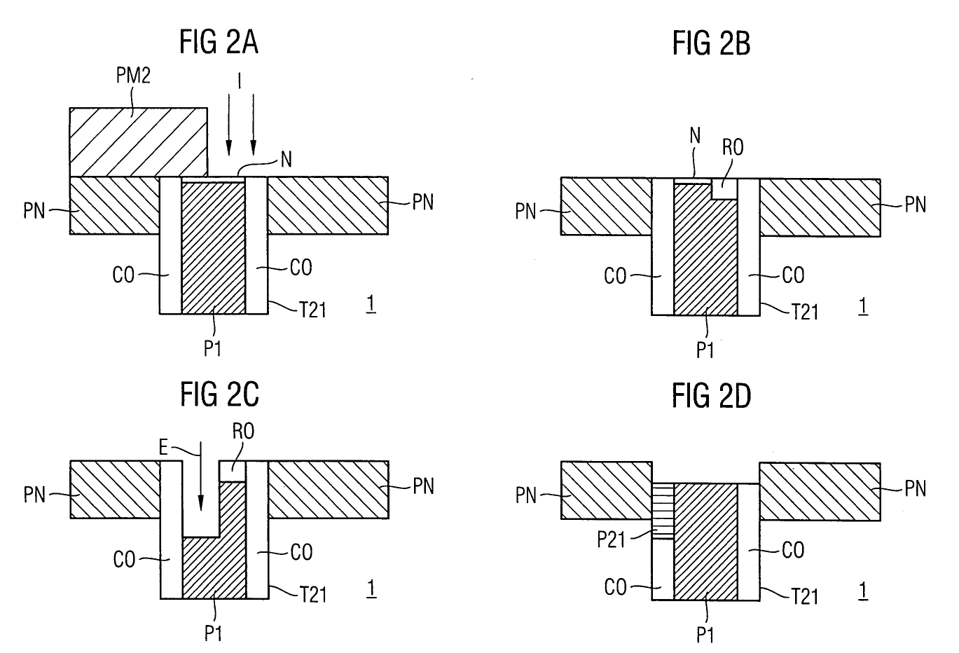

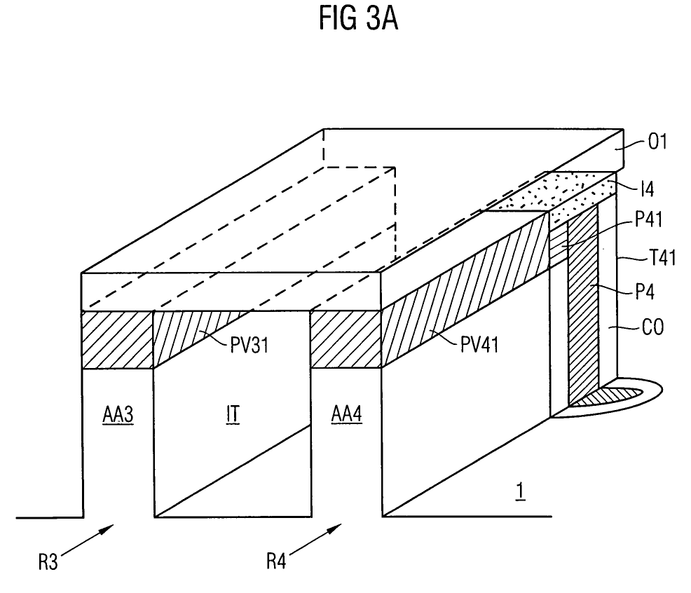

In FIG. 1A reference sign 1 denotes a silicon semiconductor substrate. Formed in the semiconductor substrate 1 is a plurality of trench capacitors T11, T12, T21, T22, T31, T32, T41, T42 having a design as depicted in FIG. 2A, namely a conductive polysilicon infill P1 surrounded by an isolation collar CO in the upper trench region. For the sake of simplicity, the medium and lower trench regions which are well known in the art are not shown here.

The trench capacitors T11, T12, T21, T22, T31, T32, T41, T42 are arranged in rows R1, R2, R3, R4 running along the x direction and columns C1, C2, C3, C4 running along the y direction which are orthogonal to each other in the x-y coordinate system. The rows R1, R2, R3, R4 and the columns C1, C2, C3, C4 are spaced by a distance 2 F from each other where F is the minimum structure width that can be resolved in the corresponding technology. Surrounded by the dotted line and denoted as CA is the area of a single memory cell in this design which equals 8 F². The trench capacitors of adjacent columns and adjacent rows are shifted by a distance of 2 F resulting in a checkerboard layout.

According to FIG. 1B and FIGS. 2A-D which show schematic cross-sections of a strap forming sequence in the manufacturing method for an integrated semiconductor structure according to said second embodiment of the present invention, single-sided connection straps are formed for the trench capacitors T11, T12, T21, T22, T31, T32, T41, T42.

With reference to FIG. 1B and FIG. 2A photomask stripes PM1, PM2 are formed on the semiconductor substrate 1 with the trench capacitors T11, T12, T21, T22, T31, T32, T41, T42. The photo-mask stripes PM1, PM2 are oriented along the Y-direction in parallel to said columns C1, C2, C3, C4 and are located between every second adjacent columns such that they cover facing parts of the trench capacitors of adjacent columns. The masked parts of the trench capacitors T11, T12, T21, T22, T31, T32, T41, T42 are the locations where the connection straps to be formed. Adjacent photomask stripes PM1, PM2 have a pitch of about 4 F.

The particular example of FIGS. 2A-2D refers to trench capacitor T21 of FIG. 1B. In FIG. 2A, reference sign PN denotes a pad nitride layer. The upper surface of the polysilicon infill P1 of trench capacitor T21 is subjected to a nitridation process for forming a thin nitridated region N. Then, an implantation step I is performed in order to destroy a part of the nitridated region N by implanting argon ions. Thereafter a reoxidation area RO is formed in the infill P1.

As depicted in FIG. 2C, the remaining nitridated region N is removed in a thinning etch step and subsequently a polysilicon etch step E is performed in order to remove polysilicon from the polysilicon infill P1 of said trench capacitor T21 to a depth which is below a surface of the semiconductor substrate 1.

With reference to FIG. 2D, an oxide etch step, a polysilicon fill step and a polysilicon recess step are performed in order to form the polysilicon connection strap P21 which forms a single-sided connection to the polysilicon infill P1.

Thereafter, as shown in FIG. 1C and 3A, insulation trenches IT are formed and filled with a dielectric such as SOG (spin on glass) or HDP oxide (high density plasma) between said rows R1, R2, R3, R4 for defining separated active areas AA1, AA2, AA3, AA4.

Then the pad nitride layer PN is removed and polysilicon connection lines PV11, PV12, PV21, PV22, PV31, PV32, PV41, PV42 are formed on said active areas AA1, AA2, AA3, AA4 between said trench capacitors T11, T12, T21, T22, T31, T32, T41, T42 each of which is electrically connected to a connection strap of an associated trench capacitor on a first side and each of which is electrically insulated from a neighboring trench capacitor of said associated trench capacitor on a second side. The insulation is effected by the collars CO. Moreover, each trech capacitor T11, T12, T21, T22, T31, T32, T41, T42 is insulated on its top by an insulating area, shown in FIG. 3A-E as region 14 which results from an chemical mechanical polishing step after filling said insulation trenches IT with said dielectric and is made of said dielectric.

Then a first oxide insulation layer O1 is deposited on said connection lines PV11, PV12, PV21, PV22, PV31, PV32, PV41, PV42 and on said filled insulation trenches IT.

As further depicted in FIG. 1C, the connection straps P11, P12, P21, P22, P31, P32, P41, P42 of the trench capacitors T11, T12, T21, T22, T31, T32, T41, T42 of each row are facing to the same direction, for example to the positive x-direction in row R1 and R3 and to the negative x-direction in rows R2 and R4. Therefore, connection straps of pairs of adjacent columns of trench capacitors are facing to each other.

In a next process step which is shown in FIG. 1D and FIGS. 3B, 3C, landing pads LP11, LP12, LP21, LP31, LP32 are formed between adjacent rows of trench capacitors in order to interconnect the connection lines of trench capacitors of adjacent rows, such as PV22 and PV31 shown in the middle of FIG. 1D. As may be obtained from FIG. 3B, in a first process step a respective via V31 is formed by a lithography/etch technique.

According to one alternative (not shown here), via V31 extends through said first insulating layer O1 and partly exposes upper portions of said connection lines PV31, PV41.

According to another alternative, as shown in FIG. 3B, via V31 extends through said first insulating layer O1 and partly extends through said connection lines PV31, PV41 and through said filled insulation trench IT and partly exposes sidewall portions of said connection lines PV31, PV41.

Thereafter, as depicted in FIG. 3C, the via V31 is filled with a conductive material such as a metal or doped polysilicon or silicids or TiN and C. One possibility to form said landing pads is to have a deposition step and a back etch or a chemical-mechanical polishing step.

In the process stage shown in FIG. 3C there is an electrical connection between the connection line PV31 and PV41 by means of landing pad LP31.

Thus, as shown in FIG. 1D, an array of landing pads LP11, LP12, LP21, LP31, LP32 etc. is formed between the different rows R1, R2, R3, R4. It should be mentioned, that the landing pads are formed in parallel to said columns C1, C2, C3, C4 and adjacent rows and columns are shifted against each other by 2 F in y-direction and by 4 F in x-direction.

Thereafter, as shown in FIG. 3D a second oxide layer O2 is formed on said first oxide layer O1 in order to have an insulation of the upper surface of the landing pads LP11, LP12, L21, LP31, LP32 etc.

In a next process step which is shown in FIG. 1E and FIGS. 3E-G, cell transistors S11, S12, S21, S22, S31, S32, S41, S42 are formed in the connecting lines PV11, PV12, PV21, PV22, PV31, PV32, PV41, PV42 which are used to control the charge flow to and from the cell trench capacitors T11, T12, T21, T22, T31, T32, T41, T42. As indicated in FIG. 1E for the landing pad LP21, the charge flow along the dashed lines L1 to trench capacitor T31 and along the dashed line L2 to trench capacitor T22 may be controlled by cell transistors S31 and S22, respectively. In other words, the two trench capacitors S31 and S22 can be connected to a single bitline which contacts the landing pad LP21 and has to be formed in a later process step.

FIG. 3F,G show a particular example of an array transistor S41 formed as a EUD (extended u-groove device) transistor.

The following steps for forming cell transistor S41 are performed. A hole H which extends through said first and second insulating layer O1, O2 and into said substrate 1 such that it divides the connection line PV41 in a first and second section PV41a, PV41b is formed in a lithography/etch step. The electrical connection between said two sections PV41a, PV41b is realized by switching on and switching off said transistor S41.

The gate conductor GP of the transistor S41 is isolated by an insulating sidewall spacer O3 from sections PV41a, PV41b and from the surrounding semiconductor substrate 1 and especially from neighboring landing pads such as landing pad LP31 shown in FIG. 1E. Only schematically shown in FIG. 3F is a gate oxide GO between the semiconductor substrate 1 and the gate conductor GP of the transistor S41. Not shown in FIG. 3F are impurity areas in the semiconductor substrate 1 which form source and drain regions of said transistor S41. Thus, individual memory cells including one cell transistor and one cell capacitor have been formed wherein one bitline may serve two memory cells.

In a next process step which is shown in FIG. 1F, wordlines WL1, WL2, WL3, WL4, WL5, WL6 are formed on said second oxide layer O2 which wordlines run in parallel to said columns C1-C4 and connect said gate conductors GP of the memory cell transistors, as shown for transistor S41 and word-line WL2 in FIG. 3F, in contact areas G11, G12, G21, G22, G31, G32, G41, G42.

Thereafter, a third insulating oxide layer O4 is deposited on the structure in order to insulate said wordlines WL1, WL2, WL3, WL4, WL5, WL6.

In a next process step, contacts C11, C12, C21, C31, C32 are formed which are connected to said landing pads LP11, LP12, LP21, LP31, LP32 etc. One example for forming said contacts C11, C12, C21, C31, C32 is a lithography/etch technique followed by a metal fill and chemical-mechanical polishing step.

Finally, bit lines BL1, BL2, BL3, BL4 are formed in parallel to said rows R1, R2, R3, R4 which are connected to said contacts C11, C12, C21, C31, C32 and run along the x-direction. Thus, a checkerboard memory cell array having two memory cells connected to a single bitline contact has been completed.

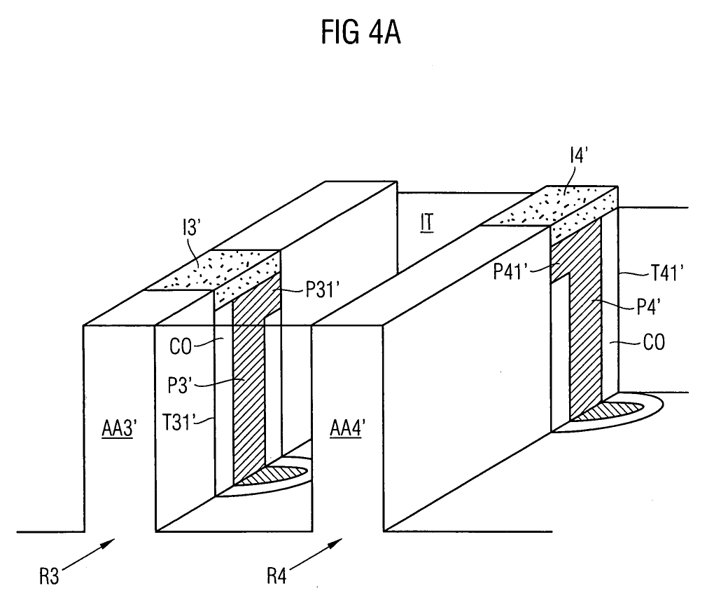

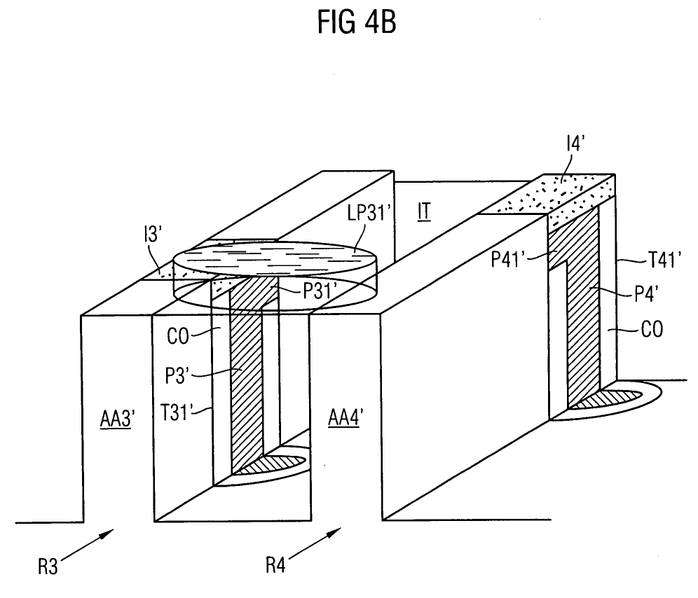

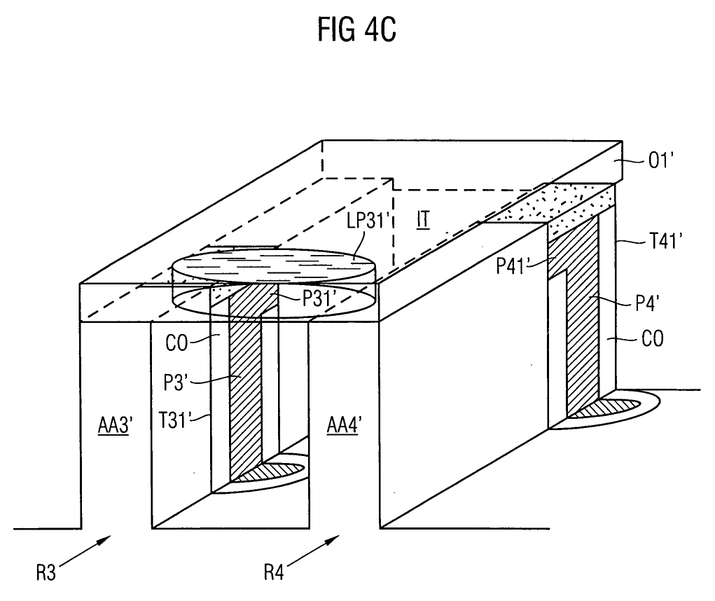

FIG. 4A-C show schematic perspective views of the manufacturing method for an integrated semiconductor structure according to a second embodiment of the present invention.

In contrast to the above-described first embodiment, according to the second embodiment there are no polysilicon connection lines on the active areas in FIG. 4A, here denoted as AA3′ and AA4′. In this embodiment the straps P41′ and P31′, respectively, are buried in the active areas AA3′ and AA4′, respectively.

Moreover, another scaling is chosen in FIG. 4A-C, such that trench capacitor T31′ with infill P3′ and buried strap P31′ and insulation region I3′ of the third row R3 and trench capacitor T41′ with infill P4′ and buried strap P41′ and insulation region I4′ of the fourth row R4 are visible. As already described above, insulation regions I3′ and I4′ result from the IT trench CMP step and cover the tops of said trench capacitor T31′ and T41′, respectively, such that the landing pads may overlap said tops.

Further with regard to FIG. 4B a polysilicon layer is deposited over the entire structure and structured with a dot mask resulting in landing pad LP31′ which is connected to both active areas AA3′ and AA4′ from above. In a next process step that is depicted in FIG. 4C an insulation layer O1′, for example an oxide layer, is deposited over the entire structure. This process state corresponds to the process state shown in FIG. 3D. In this embodiment, however, only one insulating layer O1′ is needed which provides a simpler process. The remaining process steps correspond to the ones described with reference to FIG. 3E-G.

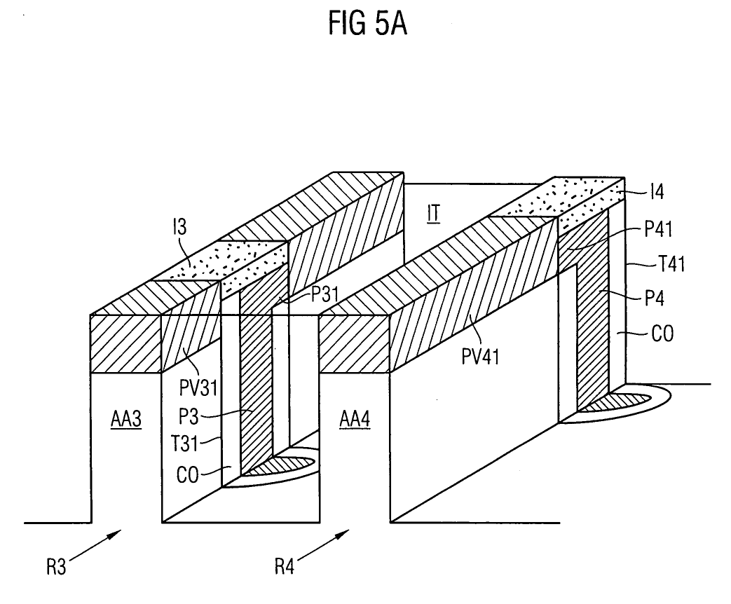

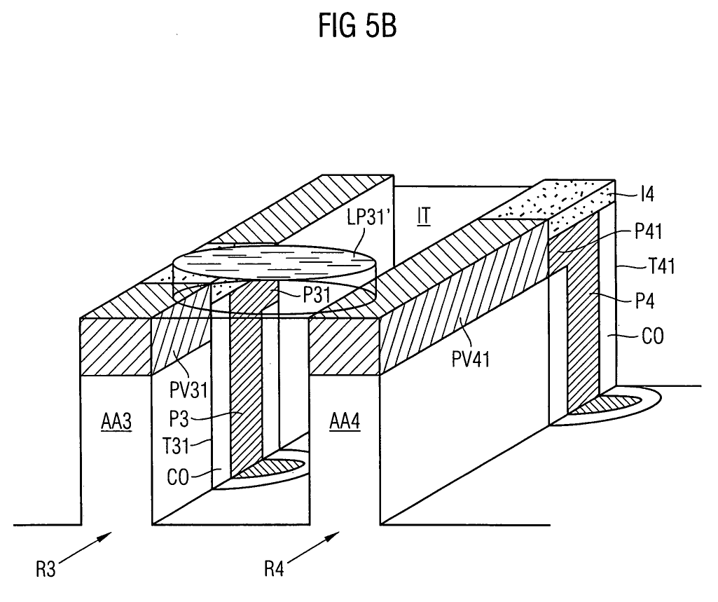

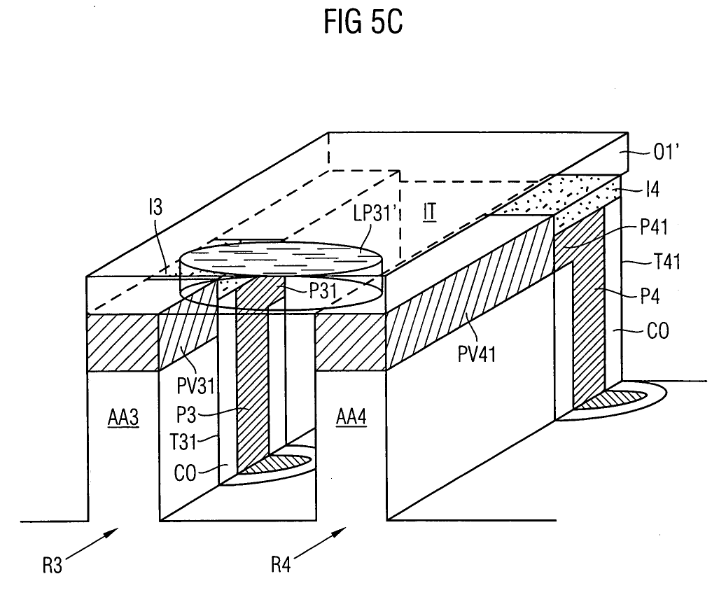

FIG. 5A-C show schematic perspective views of the manufacturing method for an integrated semiconductor structure according to a third embodiment of the present invention.

FIG. 5A corresponds to FIG. 3A with the exception that the first insulating layer O1 is omitted and that the trench capacitor T31 is shown because of a different scaling.

As further shown in FIG. 5B, a polysilicon layer is deposited and structured by a dot mask over the resulting structure, such that landing pad LP31′ results. In analogy to FIG. 4C, oxide layer O1′ is deposited over the entire structure in order to insulate landing pad LP31′, as shown in FIG. 5C.

This process state corresponds to the process state shown in FIG. 3D. In this embodiment, however, also only one insulating layer O1′ is needed which provides a simpler process. The remaining process steps correspond to the ones described with reference to FIG. 3E-G.

Although the present invention has been described with reference to a preferred embodiment, it is not limited thereto, but can be modified in various manners which are obvious for a person skilled in the art. Thus, it is intended that the present invention is only limited by the scope of the claims attached herewith.

1. A manufacturing method for an integrated semiconductor structure comprising the steps of:
providing a semiconductor substrate having a plurality of trench capacitors which are arranged in rows and columns in a checkerboard layout;
forming connection straps for electrically connecting said trench capacitors such that the connection straps of pairs of adjacent columns are facing each other,
forming insulation trenches between said rows for defining active areas, each of which active areas is electrically connected to a connection strap of an associated trench capacitor on a first side and each of which is electrically insulated from a neighboring trench capacitor of said associated trench capacitor on a second side;
forming electrically conducting landing pads between adjacent active areas for connecting pairs of said active areas, said landing pads being arranged in first lines in parallel to said columns;
forming an insulation layer on said first insulating layer (O1) covering said landing pads; and
forming a cell transistor for each trench capacitor which divides the active area of the associated trench capacitor in a first and second section, said cell transistors being arranged in second lines in parallel to said columns.

2. The method according to claim 1, further comprising the step of:
forming connection lines on said active areas between said trench capacitors, each of which is electrically connected to a connection strap of an associated trench capacitor on a first side and each of which is electrically insulated from a neighboring trench capacitor of said associated trench capacitor on a second side, said electrically conducting landing pads being formed between said connection lines, said cell transistor dividing the connection lines of the associated trench capacitor in a corresponding first and second section.

3. The method according to claim 2, further comprising the step of:
forming another insulation layer on said connection lines and on said insulation trenches.

4. The method according to claim 1, further comprising the step of:
forming wordlines on said another insulating layer which are electrically connected to respective groups of cell transistors arranged along said second lines.

5. The method according to claim 3, further comprising the steps of:
forming a third insulating layer on said second insulating layer covering said wordlines;
forming bitline contacts for connecting said landing pads which extend through said first, second and third insulating layer; and
forming bitlines on said third insulating layer which are electrically connected to respective groups of bitline contacts arranged in parallel to said rows.

6. The method according to claim 1, wherein said step of forming connection straps comprises:
forming mask stripes between said columns which partly mask a conductive infill of the trench capacitors of pairs of adjacent columns;
performing an ion implantation into the not masked parts of said conductive infill of said trench capacitors in order to destroy a part of a nitridated region by implanting argon ions;
reoxidating the not masked parts of said conductive infill;
removing said mask stripes;
etching back a part of said conductive infill and a surrounding insulating collar;
refilling said trench capacitors with another conductive infill; and
etching back said another conductive infill such that connection straps are formed.

7. The method according to claim 1, wherein said step of forming said landing pads comprises:
forming vias which extend through said first insulating layer and which partly expose upper portions of said connection lines; and
filling said vias with a electrically conductive material which electrically contacts said exposed upper portions.

8. The method according to claim 1, wherein said step of forming said landing pads comprises:
forming vias which extend through said first insulating layer and which partly extend through said connection lines and said insulation trenches and which partly expose sidewall portions of said connection lines; and
filling said vias with a electrically conductive material which electrically contacts said sidewall portions.

9. The method according to claim 1, wherein said step of forming said landing pads comprises:
depositing a conductive layer and structuring said landing pads by means of a dot mask.

10. The method according to claim 2, wherein said connection lines are made of polysilicon.

11. The method according to claim 1, wherein said cell transistor are EUD transistors or FINFET-like transistors.

12. The method according to claim 3, wherein said insulating layers are silicon oxide or nitride layers.

13. The method according to claim 2, wherein said step of forming a cell transistor comprises:
forming a hole which extends through said first and second insulating layer and into said substrate such that it divides the connection line of the associated trench capacitor in said first and second section; and
forming a gate in said hole which is electrically insulated by a sidewall spacer in the upper portion of said hole.

14. A manufacturing method for an integrated semiconductor structure comprising the steps of:
providing a semiconductor substrate having a plurality of trench capacitors which are arranged in rows and columns in a checkerboard layout;
forming connection straps for electrically connecting said trench capacitors such that the connection straps of pairs of adjacent columns are facing each other;
forming insulation trenches between said rows for defining active areas;
forming connection lines on said active areas between said trench capacitors each of which is electrically connected to a connection strap of an associated trench capacitor on a first side and each of which is electrically insulated from a neighboring trench capacitor of said associated trench capacitor on a second side;
forming electrically conducting landing pads between adjacent connection lines for connecting pairs of said connection lines, said landing pads being arranged in first lines in parallel to said columns;
forming a cell transistor for each trench capacitor which divides the connection line of the associated trench capacitor in first and second section, said cell transistors being arranged in second lines in parallel to said columns.

15. The method according to claim 14, wherein said step of forming said landing pads comprises:
forming vias which partly expose upper portions of said connection lines; and
filling said vias with a electrically conductive material which electrically contacts said exposed upper portions.

16. The method according to claim 14, wherein said step of forming said landing pads comprises:
forming vias which partly extend through said connection lines and said insulation trenches and which partly expose sidewall portions of said connection lines; and
filling said vias with a electrically conductive material which electrically contacts said sidewall portions.

17. An integrated semiconductor structure comprising:
a semiconductor substrate having a plurality of trench capacitors which are arranged in rows and columns in a checkerboard layout;
connection straps for electrically connecting said trench capacitors such that the connection straps of pairs of adjacent columns are facing each other;
connection lines on said active areas between said trench capacitors each of which is electrically connected to a connection strap of an associated trench capacitor on a first side and each of which is electrically insulated from a neighboring trench capacitor of said associated trench capacitor on a second side;
electrically conducting landing pads between adjacent connection lines for connecting pairs of said connection lines, said landing pads being arranged in first lines in parallel to said columns;
a cell transistor for each trench capacitor which divides the connection line of the associated trench capacitor in first and second section, said cell transistors being arranged in second lines in parallel to said columns.

18. The structure according to claim 14, further comprising:
wordlines which are electrically connected to respective groups of cell transistors arranged along said second lines.

19. The structure according to claim 18, further comprising:
bitline contacts for connecting said landing pads;
bitlines which are electrically connected to respective groups of bitline contacts arranged in parallel to said rows.

20. An integrated semiconductor structure comprising:
a semiconductor substrate having a plurality of trench capacitors which are arranged in rows and columns in a checkerboard layout;
connection straps for electrically connecting said trench capacitors such that the connection straps of pairs of adjacent columns are facing each other;
insulation trenches between said rows for defining active areas;
connection lines on said active areas between said trench capacitors each of which is electrically connected to a connection strap of an associated trench capacitor on a first side and each of which is electrically insulated from a neighboring trench capacitor of said associated trench capacitor on a second side;
a first insulation layer on said connection lines and on said insulation trenches;
electrically conducting landing pads between adjacent connection lines for connecting pairs of said connection lines, said landing pads being arranged in first lines in parallel to said columns;
a second insulation layer on said first insulating layer covering said landing pads; and
a cell transistor for each trench capacitor which divides the connection line of the associated trench capacitor in first and second section, said cell transistors being arranged in second lines in parallel to said columns.

21. The structure according to claim 20, further comprising:
wordlines on said second insulating layer which are electrically connected to respective groups of cell transistors arranged along said second lines.

22. The structure according to claim 21, further comprising:
a third insulating layer on said second insulating layer covering said wordlines;
bitline contacts for connecting said landing pads which extend through said first, second and third insulating layer; and
bitlines on said third insulating layer which are electrically connected to respective groups of bitline contacts arranged in parallel to said rows.
